(19) United States
(12) Patent Application Publication
(10) Pub. No.: US 2026/0268192 A1
(43) Pub. Date: Sep. 10, 2026

(54) QUANTUM BIT ARRAY AND METHOD OF CONTROLLING QUANTUM BIT

(71) Applicant: Hitachi, Ltd., Tokyo (JP)

(72) Inventors: Takeru UTSUGI, Tokyo (JP); Go SHINKAI, Tokyo (JP); Tomonori SEKIGUCHI, Tokyo (JP)

(21) Appl. No.: 18/876,235

(22) PCT Filed: Sep. 8, 2022
(86) PCT No.: PCT/JP2022/033660

§ 371 Date: Dec. 18, 2024

(51) Int. Cl. G06N 10/40

(52) U.S. Cl. CPC G06N 10/40

(57) ABSTRACT

In a dynamic resonance frequency changing method, there is a problem in phase tracking, and there is a concern that an error of a single-qubit gate occurs. The solution is a method of controlling a quantum bit that controls a spin state of a quantum bit formed by a charge trapped in a semiconductor device. The method includes: when controlling a spin state of a quantum bit formed by a target charge specified by a first line and a second line formed in the semiconductor device, executing a first step of measuring at least one of a current and a charge amount flowing through the first line and the second line; and executing a second step of controlling at least one of the current and the charge amount flowing through the first line and the second line based on a measurement result of the first step.

### TECHNICAL FIELD

The present invention relates to a device for integrating quantum bits and a method of controlling the device.

### BACKGROUND ART

Quantum computers are considered to be capable of high-speed information processing as compared with existing computers. While an existing computer handles binary values 0 and 1, a quantum computer can handle overlapped states of the two values.

In order to handle the overlapped state, a quantum computer requires an element that implements a quantum bit. The quantum bit can be implemented by using a superconducting element, a cold atom, a photon, a quantum dot formed by a semiconductor element, or the like. Basic operations of a quantum computer include initialization, calculation, and readout, and further include a single-qubit gate, a two-qubit gate, and the like as basic calculation, and it is known that universal quantum computation can be implemented by combining these.

Here, a method of implementing the single-qubit gate in a quantum bit using a semiconductor element will be described. Each quantum bit to which a static magnetic field is applied in a Z direction has a resonance frequency depending on each element and a magnitude of the static magnetic field. By performing irradiation with a microwave having the same frequency as the resonance frequency, a state of the quantum bit can be changed by an action called a Rabi oscillation.

An actual quantum computer has a large number of quantum bits, and it is necessary to selectively perform an operation on each quantum bit. In order to achieve selective operation, it is necessary to prevent the resonance frequencies of the quantum bit to be controlled and the quantum bit not to be controlled from overlapping.

In the related art, a control method (hereinafter, referred to as a “fixed resonance frequency method”) of setting (assigning) a unique resonance frequency to each quantum bit is used. However, since a frequency is a finite resource, it can be easily conceived that it is difficult to set different resonance frequencies for all quantum bits when the number of quantum bits to be handled is large. Actually, 1,000,000 quantum bits are required to solve practical problems, and it is difficult to control all the quantum bits in the fixed resonance frequency method. Therefore, a method of frequency-dividing a selected quantum bit by changing a resonance frequency of a quantum bit to be controlled (selected quantum bit) with respect to a quantum bit not to be controlled (non-selected quantum bit) has been studied.

PTL 1 discloses a circuit configuration that allows each of a plurality of quantum bits to have adjustable resonance frequency, which may make it possible to avoid the above-described problem.

### CITATION LIST

### Patent Literature

PTL 1: JP2018-532255A

### SUMMARY OF INVENTION

### Technical Problem

The PTL does not describe a problem of a phase shift that occurs when a frequency of the selected quantum bit is changed. Each quantum bit, which uses a degree of freedom of an electron spin due to a semiconductor element to which a static magnetic field is applied in a Z direction, can be considered to perform a precession with a Z axis as a rotation center at each resonance frequency. A frequency of the precession is approximately proportional to a magnitude (magnetic flux density) of the applied static magnetic field. Therefore, by locally changing a magnitude of a static magnetic field applied to the selected quantum bit, a different resonance frequency can be given to the quantum bit, and by irradiating the selected quantum bit with a microwave that matches the resonance frequency, it is possible to perform a single-qubit gate operation on only the selected quantum bit (hereinafter, this will be referred to as a dynamic resonance frequency changing method).

Here, in a quantum computer in which spins that make a precession are used as quantum bits, a phase of microwaves for irradiation relative to a phase of the precession of spins determines which axis in an XY plane is a rotation axis for the single-qubit gate operation. Therefore, it is necessary to constantly track phases of precessions of all quantum bits during quantum computation.

However, in the dynamic resonance frequency changing method in which a resonance frequency of the selected quantum bit is varied relative to another non-selected quantum bit, it is difficult to constantly track phase fluctuations accompanying frequency fluctuations. This is because, in order to constantly track fluctuations of the resonance frequency, it is necessary to constantly track fluctuations in a magnitude of the static magnetic field (sensed by the quantum bit) at each quantum bit position, which is considered to be technically difficult. Monitoring the phase by directly measuring the quantum bit in real time is also difficult in terms of a nature of “a change in a quantum state due to measurement” of the quantum bit.

Thus, in the dynamic resonance frequency changing method, there is a problem in phase tracking, and there is a concern that an error of a single-qubit gate occurs.

### Solution to Problem

A representative example of the invention disclosed in the present application is as follows. That is, a quantum bit array includes: a semiconductor layer; an insulating layer provided on the semiconductor layer; a plurality of first electrodes provided on the insulating layer and configured to trap a charge in a predetermined spin state in the semiconductor layer by applying a voltage; a plurality of second electrodes provided on the insulating layer and configured to form a magnetic field acting on the charge by passing a current; a current applying unit configured to pass a current to at least one of the second electrodes to form a magnetic field acting on the charge when the spin state of the charges is changed; a microwave generating source configured to irradiate the charge with a microwave; and a current measuring unit configured to measure a current flowing through the second electrode.

According to another aspect of the invention, there is provided a method of controlling a quantum bit that controls a spin state of a quantum bit formed by a charge trapped in a semiconductor device. The method of controlling a quantum bit includes: when controlling a spin state of a quantum bit formed by a target charge specified by a first line and a second line formed in the semiconductor device, executing a first step of measuring at least one of a current and a charge amount flowing through the first line and the second line; and executing a second step of controlling at least one of the current and the charge amount flowing through the first line and the second line based on a measurement result of the first step.

### Advantageous Effects of Invention

In a dynamic resonance frequency changing method, it is possible to cope with occurrence of an error in a single-qubit gate. The problems, configurations, and effects other than those described above will become apparent in the following description of embodiments.

### BRIEF DESCRIPTION OF DRAWINGS

FIG. 1 is a two-plane view of a two-dimensional quantum bit array according to an embodiment.

FIG. 2 is a schematic block diagram of a system for performing a single-qubit gate.

FIG. 3 is a graph showing changes over a time t in a current value, a resonance frequency f_{q1} of a selected quantum bit, a resonance frequency f_{q2} of a non-selected quantum bit, an amplitude B_{rb} of a magnetic flux density of a microwave pulse, and a resulting Rabi frequency f_{rb} of the selected quantum bit in a dynamic resonance frequency changing method.

FIG. 4A is a graph showing changes in phases of the selected quantum bit and the non-selected quantum bit over time.

FIG. 4B is a graph showing a frequency change in the selected quantum bit.

FIG. 4C is a graph showing a relationship between gate fidelity and a phase shift.

FIG. 5 is a block diagram showing a system configuration for measuring a current flowing through an interconnect or a charge amount flowing through the interconnect with high accuracy.

FIG. 6 is a block diagram showing a configuration for detecting current values or charge amounts of a plurality of interconnects in a small number of currents or charge readout units.

FIG. 7A is a flowchart showing an example of a calibration method.

FIG. 7B is a table showing an example of calibration data.

FIG. 7C is a table showing an example of correction data set based on calibration data.

FIG. 8A is a classification diagram of quantum bits in a quantum bit array.

FIG. 8B is a graph showing changes over time in resonance frequencies of three types of quantum bits.

FIG. 9A is graph showing a decrease in F due to crosstalk.

FIG. 9B is a graph showing a decrease in F due to crosstalk in a LOG scale with a vertical axis as 1−F.

FIG. 9C is a graph showing a change over time in a resonance frequency of a selected quantum bit by a single irradiation method.

FIG. 9D is a graph showing a change over time in a resonance frequency of the selected quantum bit by another single irradiation method.

FIG. 9E is a graph showing a change over time in a resonance frequency of the selected quantum bit by a twice irradiation method.

FIG. 10A is a graph showing a decrease in F due to crosstalk by the single irradiation method.

FIG. 10B is a graph showing a decrease in F due to crosstalk by the single irradiation method in a LOG scale with a vertical axis as 1−F.

FIG. 10C is a graph showing a decrease in F due to crosstalk by the twice irradiation method.

FIG. 10D is a graph showing a decrease in F due to crosstalk by the twice irradiation method in a LOG scale with a vertical axis as 1−F.

FIG. 10E is a graph showing a relationship between an angle θ of a quantum gate operation and x.

FIG. 10F is a graph showing a relationship between the angle θ of a quantum gate operation and x.

FIG. 10G is a graph showing a relationship between the angle θ of a quantum gate operation and x.

FIG. 11 is a conceptual diagram of the twice irradiation method.

FIG. 12A is a conceptual diagram of a three-gate method.

FIG. 12B is a quantum circuit diagram showing Embodiment 3.

FIG. 13A is a plan view showing contour lines of a static magnetic field distribution generated when currents flow through Iₐ, I_{b}, I_{c}, and I_{d} in directions of arrows.

FIG. 13B is a schematic diagram of an N-gate method according to Embodiment 4.

### DESCRIPTION OF EMBODIMENTS

Embodiments will be described in detail with reference to the drawings. The invention is not to be construed as being limited to the description of the embodiments described below. It will be easily understood by those skilled in the art that the specific configuration can be changed without departing from the spirit or scope of the invention.

In the configurations of the embodiments described below, the same portions or portions having similar functions are denoted by the same reference signs in different drawings, and redundant description thereof may be omitted.

When there are a plurality of components having the same or similar functions, the description may be made by assigning the same reference signs thereof with different subscripts. However, when it is not necessary to distinguish the plurality of components, the description may be made by omitting the subscripts.

Notations “first”, “second”, “third”, and the like in the present specification are provided to identify components and do not necessarily limit the number, the order, or the content thereof. A number for identifying a component is used for each context, and a number used in context does one not necessarily indicate the same configuration in another context. This does not prevent a component identified by a certain number from also having a function of a component identified by another number.

In order to facilitate understanding of the invention, a position, magnitude, shape, range, and the like of each configuration shown in the drawings or the like may not represent an actual position, magnitude, shape, range, or the like. Therefore, the invention is not necessarily limited to positions, magnitudes, shapes, ranges, and the like disclosed in the drawings, or the like.

Publications, patents, and patent applications cited in the present specification constitute a part of the description of the present specification as they are.

In the present specification, a component represented by a single form includes a plural form unless the context clearly indicates otherwise.

The embodiment focuses on a phase shift of a selected quantum bit to which a local magnetic field is applied by a current in a quantum bit array chip using electron spins in silicon. In the embodiment, it is possible to estimate a phase shift generated during a frequency shift by detecting a current value or a charge amount flowing through an interconnect for applying a local magnetic field to spins. As a result, calibration can be executed by utilizing a phase shift amount, and high fidelity of a quantum gate operation is achieved.

As a specific circuit, in a frequency fluctuation method, a charge amount is stored and read by a circuit that accumulates currents when a local magnetic field is applied, and a phase shift amount is estimated based on the obtained charge amount and used for calibration.

### Embodiment 1

### [Basic Configuration]

A quantum computer using an electron spin using a semiconductor element as a quantum bit will be described. The quantum computer has a plurality of two-dimensional quantum bit arrays.

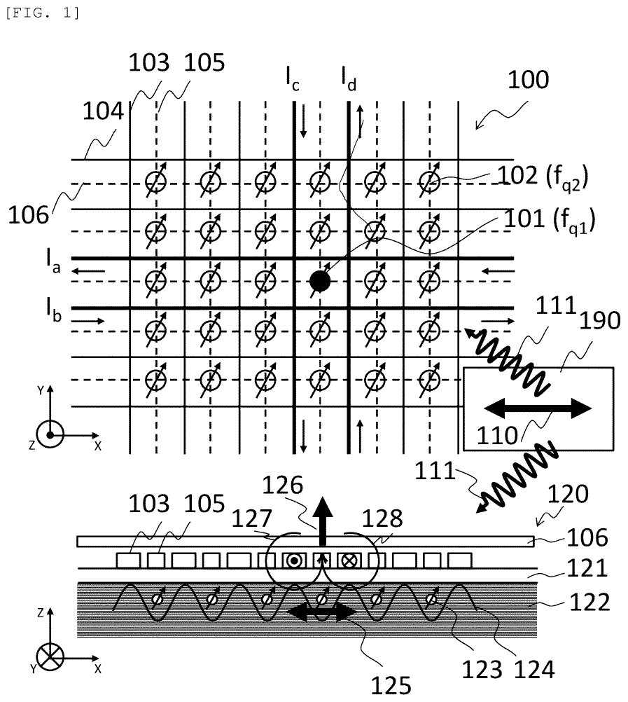

FIG. 1 is a schematic diagram of a two-dimensional quantum bit array. This figure shows a part of a quantum bit array 100 having a large number of quantum bits. The quantum bit array 100 is mounted in a chip placed under an extremely low temperature of several mK to several K.

A quantum bit 101 is a selected quantum bit to be controlled, and other quantum bits (for example, 102) are non-selected quantum bits. An interconnect 103 and an interconnect 104 have a composite structure of an interconnect and a gate electrode provided between quantum bits in a Y direction and an X direction, and are used to generate a local magnetic field by passing a current to be described later. The interconnect 103 and the interconnect 104 can also be used for a gate electrode for controlling strength of coupling between electron spins, and a two-qubit gate can be implemented by exchange interaction. An interconnect 105 and an interconnect 106 have a composite structure of an interconnect and a gate electrode provided between quantum bits in the Y direction and the X direction, and are used as gate electrodes for trapping electrons to be quantum bits.

A cross-sectional view 120 is a cross-sectional view of the quantum bit array 100 taken along a line having a quantum bit, such as an interconnect 106, and has a metal oxide insulator (MOS) structure including a gate electrode layer formed by an insulating layer 121, a semiconductor layer 122, and interconnects 103 and 105 constituting a plurality of gate electrodes.

By adjusting a voltage applied to the gate electrodes of the interconnect 103 and the interconnect 105, a potential 124 is generated in the semiconductor layer 122, and an electron 123 and the like are trapped. The drawings are schematic diagrams in which a part of the quantum bit array 100 is enlarged, and actual gate dimensions and thicknesses of layers do not represent actual dimensions.

### [Single-Qubit Gate Operation]

Up and down states of an electron spin are 0 and 1 states of the quantum bit. At this time, an overlapped state of 0 and 1 can be physically generated by an overlapped state of up and down of the electron spin, and quantum computation can be executed. An operation of rotating a direction of the electron spin by any angle corresponds to an operation of the single-qubit gate. This operation is performed by a Rabi oscillation caused by performing irradiation with a microwave pulse 111 that matches the resonance frequency of the electron spin.

In FIG. 1, a substantially uniform static magnetic field is applied across an entire surface in a Z direction. The static magnetic field has a magnetic flux density of several tens of mT to several T according to a superconducting magnet or the like. A frequency of a precession of spins is substantially proportional to an applied magnetic field (magnetic flux density). Each spin has a precession at a Z-axis center of, for example, several tens of GHz. Here, an oscillating magnetic field produced by the microwave pulse 111 is used to perform irradiation so that a polarization direction 110 is, for example, the X direction. The polarization direction may be any direction in an XY plane.

The microwave pulse 111 is substantially uniformly applied to the entire surface of the quantum bit array 100. Therefore, by selectively changing the resonance frequency of the spin, only a desired spin is made to resonate with a frequency of the microwave pulse. As a result, it is possible to cause a Rabi oscillation only in a desired spin, and to execute a single-qubit gate operation.

A rotation axis of the spin due to the Rabi oscillation is limited to the XY plane in this configuration, and a direction of the rotation axis in the XY plane is determined by a relative phase between a phase of the microwave pulse and a phase of the spin. That is, by precisely controlling the phase of the microwave pulse, the spin can be rotated around an axis in any direction in the XY plane. Any single-qubit gate operation can be performed by continuously performing irradiation with the microwave pulse by changing the rotation axis (that is, changing the phase of the microwave pulse) at least twice.

The microwave pulse 111 is generated by a microwave generating antenna structure 190 shown in FIG. 1. This antenna structure is implemented by an electromagnetic field leaking from a radio-frequency transmission line structure, such as a microstrip line structure or a coplanar waveguide structure.

### [Dynamic Resonance Frequency Changing Method]

In order to select a desired quantum bit, a local magnetic field generated by passing a current through an interconnect such as the interconnects 103 and 104 is used. For example, current flows in directions of arrows through four lines Iₐ, I_{b}, I_{c}, and I_{d} in FIG. 1. Here, currents in opposite directions flow through two parallel interconnects forming a pair. Since the currents Iₐ and I_{b} in the X direction perform quantum bit selection in the Y direction and the currents I_{c} and I_{d} in the Y direction perform quantum bit selection in the X direction, the quantum bit 101 at an intersection is selected.

First, one-dimensional quantum bit selection will be described with reference to the cross-sectional view 120. When a direct current flows through the interconnect, static magnetic fields 127 and 128 are generated, and a combined magnetic field 126 is generated between the interconnects. Here, static magnetic fields in the same direction are strengthened, and magnetic fields in opposite directions are weakened. Since a local Z direction static magnetic field is applied to the quantum bit at a position where the magnetic fields are strengthened, a resonance frequency difference substantially proportional to a magnitude of the applied local static magnetic field can be given to a quantum bit relative to other surrounding quantum bits, making it possible to select the quantum bit. The resonance frequency of the selected quantum bit can be varied by turning on and off a current and adjusting a current value.

It is easy to two-dimensionally expand the one-dimensional quantum bit selection described above. When the quantum bit selection described above is performed in each of the X direction and the Y direction, only a quantum bit at an intersection has a resonance frequency different from that of surroundings, and thus two-dimensional quantum bit selection is possible. Therefore, by applying a microwave pulse having a frequency that matches a resonance frequency of the selected quantum bit having polarized light 125 in the X direction, only the selected quantum bit 101 can cause Rabi oscillations, and the single-qubit gate can be achieved.

### [System Diagram]

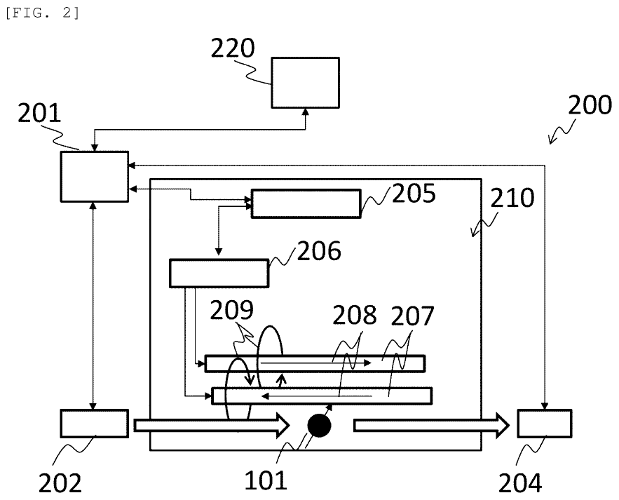

FIG. 2 is a schematic block diagram of a system 200 for performing the single-qubit gate. A host 220 is, for example, a general computer that controls the entire system. When a command for performing the single-qubit gate is issued from the host 220 to a control unit 201, the control unit 201 sends a quantum bit address for performing a gate operation and parameter information various gate operations to a controller 205 in a dynamic resonance frequency changing unit 210. The quantum bit address is an address for designating which quantum bit in the quantum bit array is to be subjected to a gate operation, and can be specified by, for example, assigning a number to the interconnects 105 and 106 and identifying an intersection thereof in FIG. 1.

The controller 205 issues a command to a current applying unit 206 based on the information. The current applying unit 206 causes a current 208 to flow through the interconnect 207 (corresponding to the interconnects 103 and 104 in FIG. 1) corresponding to the designated quantum bit address to generate a local static magnetic field 209. The interconnect 207 and the quantum bit are formed of the semiconductor element shown in FIG. 1, and are maintained at an extremely low temperature as described above. Here, the current flowing through the interconnect 207 is sent to an outside of a chip through an interconnect (not shown), and prevents heat generation in the chip in order to maintain an extremely low temperature environment near the quantum bit.

Further, when a command is issued from the control unit 201, a microwave pulse generation unit 202 generates the microwave pulse 111 whose frequency is adjusted and irradiates the quantum bit array with the microwave pulse 111. Accordingly, the single-qubit gate can be selectively applied to the selected quantum bit 101 according to a principle of the dynamic resonance frequency changing method. When a state of the quantum bit is read out, a quantum state of the selected quantum bit 101 is measured using a readout unit 204.

Although only one quantum bit and two interconnects are shown in FIG. 2, there are a plurality of quantum bits and interconnects as shown in FIG. 1 in practice, and there is a configuration necessary for trapping, initializing, reading out, and operating a two-qubit gate for electrons.

### [Dynamic Frequency]

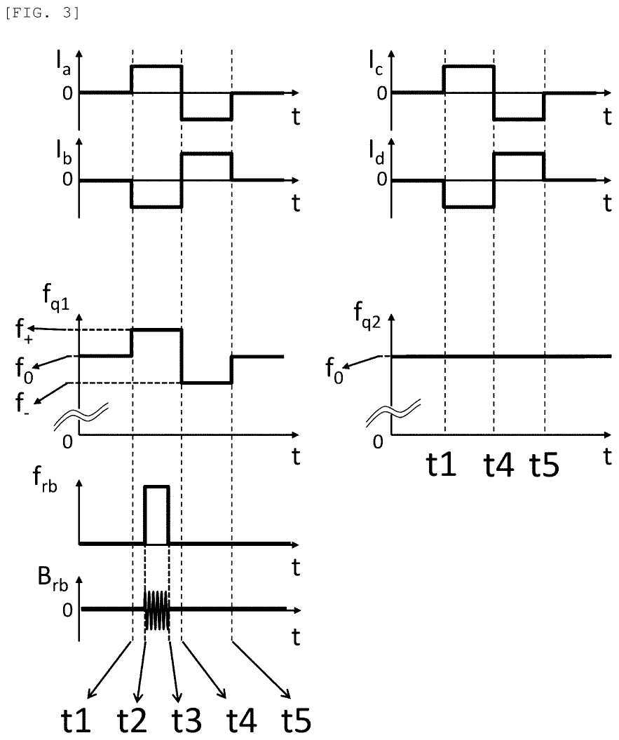

FIG. 3 shows changes over a time t in the dynamic resonance frequency changing method in current values of Iₐ to I_{d} in FIG. 1, a resonance frequency f_{q1} of the selected quantum bit 101, a resonance frequency f_{q2} of the non-selected quantum bit 102, an amplitude B_{rb} of a magnetic flux density of the microwave pulse 111, and a resulting Rabi frequency f_{rb} of the selected quantum bit 101.

When a current flows through Iₐ to I_{d} in FIG. 1, a static magnetic field is generated, and the selected quantum bit 101 has the resonance frequency f_{q1} depending on a magnitude of the static magnetic field. By performing irradiation with the microwave pulse 111 whose resonance frequency matches the resonance frequency f_{q1}, a rotation axis of the selected quantum bit spin can be controlled to any angle, which serves as an action of a one-bit quantum operation. As described above, the direction of the rotation axis in the XY plane is determined by the relative phase between the phase of the microwave pulse and the phase of the spin.

The inventors focus on a phenomenon in which the currents Iₐ to I_{d} do not reach initially intended values due to parasitic capacitance, resistance, or the like, and the static magnetic field is not stable, and thus the resonance frequency is not stable. Due to this phenomenon, control over the relative phase between the phase of the microwave pulse and the phase of the spin cannot be executed according to theory, and ultimately, the problem is discovered that a spin rotation axis cannot be precisely controlled.

Times t1 and t4 are start and end times of resonance frequency fluctuations in a plus direction in the selected quantum bit 101. Times t2 and t3 are start and end times of application of the microwave pulse 111. Times t4 and t5 are start and end times of a resonance frequency fluctuation in a minus direction in the selected quantum bit 101.

A reason why the resonance frequency of the selected quantum bit 101 is varied in both the plus direction and the minus direction is to avoid occurrence of a phase shift of the selected quantum bit with respect to the non-selected quantum bit due to fluctuations in the resonance frequency. Iₐ and I_{b} are parallel interconnects as shown in FIG. 1, and current flows in opposite directions. The same applies to I_{c} and I_{d}. In a period of t2 to t3 and a period of t3 to t4, formed magnetic fields have, for example, the same magnitude but the opposite direction. Accordingly, the resonance frequency f_{q1} of the selected quantum bit shifts in the plus direction from a resonance frequency f₀ when no current flows to f₊ in a period from t1 to t4.

In a period from t4 to t5, conversely, there is a shift in the minus direction to f₋. On the other hand, since the resonance frequency f_{q2} of the non-selected quantum bit 102 is not affected by the local magnetic field, the resonance frequency f₀ remains unchanged. The microwave pulse 111 having a frequency that matches the resonance frequency f₊ of the selected quantum bit is applied in a period from t2 to t3 to generate a Rabi oscillation only in the selected quantum bit. Here, a Rabi frequency f_{rb}, which is a frequency of the Rabi oscillation, is substantially proportional to the amplitude B_{rb} of the magnetic flux density sensed by the spin, and contributes to a speed of the single-qubit gate operation. Here, there is a relationship (t4−t1)=(t5−t4)>(t3−t2). By satisfying the relationship, the single-qubit gate operation can be performed correctly. An order of plus and minus of the resonance frequency fluctuation may be reversed, and a timing of irradiation with the microwave pulse may be either plus or minus of the resonance frequency fluctuation or both.

### [Phase Tracking]

In the single-qubit gate operation, the phase of spin is important as described above. Since the phase is a relative concept, both the phase of the quantum bit and the phase of the microwave pulse at the time t2 when the microwave pulse 111 is applied at the beginning of quantum computation are defined as an initial phase 0 (phase difference 0). Since there is some flexibility in this definition, any phase and any phase difference may be used.

From the time t2, the control unit 201 has a reference clock that matches the resonance frequency of the quantum bit, and has a function of tracking and counting the phase of the quantum bit using the reference clock (phase tracking function). With regard to the phase tracking using such a reference clock, for example, there are documents such as “The role of master clock stability in quantum information processing” Harrison Ball, William D Oliver and Michael J Biercuk. npj Quantum Information (2016) 16033. It is important to note that, if the phase is reset during the quantum computation, tracking of the phase of the quantum bit that continues to rotate cannot be performed (the phase is lost), and therefore, the phase tracking cannot be reset during the quantum computation.

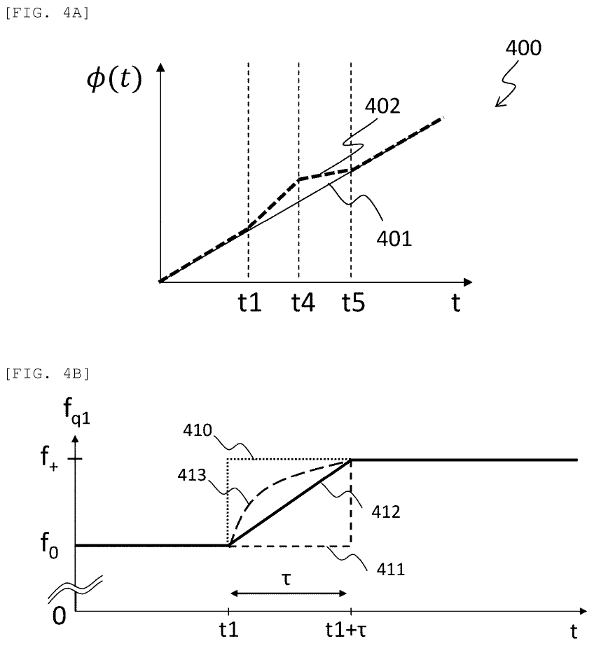

FIG. 4A shows a change in the phase φ(t) of the quantum bit over time when the operation of FIG. 3 is performed. Here, a phase 402 of the selected quantum bit and a phase 401 of the non-selected quantum bit are shown together. A phase shift due to a frequency shift occurs in both phases. Using this phase shift, a desired quantum bit is selectively manipulated. Here, phase can be expressed as (time integral of frequency)×2π.

That is, there is a relationship of Formula 1.

$$\begin{matrix}[ Math . 1 ] & \\ ϕ ( t ) = 2 π {\int }_{0}^{t} f ( {t}^{′} ) {dt}^{′} & ( Formula 1 )\end{matrix}$$

Therefore, φ(t) becomes a straight line rising to a right when the frequency is constant, and a slope of the straight line changes when the frequency fluctuates. The slope of the straight line (time derivative of the phase) corresponds to a value obtained by multiplying the resonance frequency of the quantum bit at that time by 2π (referred to as angular frequency).

That is, there is a relationship of Formula 2.

$$\begin{matrix}[ Math . 2 ] & \\ 2 π f ( t ) = \frac{d ϕ ( t )}{dt} & ( Formula 2 )\end{matrix}$$

In a fixed resonance frequency method, since the frequency of each quantum bit is constant, the phase linearly increases with time (repeats at a 2π period). Therefore, the phase tracking can also be easily achieved by using the above-described highly accurate reference clock signal, but is not suitable for large-scale integration for the above-described reason. In the dynamic resonance frequency changing method, when a reference clock signal is used, there is a problem of phase tracking shown below at frequency switching portions at the t1, t4, and t5.

The problem of the phase tracking will be described using a specific example. For example, in order to know at any time a current phase (which cannot be measured directly) of a precession of a quantum bit at 20 GHz, a 20 GHz reference clock (sine wave) is prepared and the phase of the reference clock is assumed to be match the phase of the precession. In this way, when applying the microwave, the phase of the microwave can be set using phase information on the reference clock. That is, the “tracking and counting of the phase” is synonymous with “using the phase information on the reference clock”.

Here, when the precession of the quantum bit deviates from 20 GHz due to some noise factor, the phase of the quantum bit and the phase of the reference clock also deviate, but the change cannot be directly measured. However, if the noise factor is caused by rise of the applied current described in FIG. 4B below, it is considered that a phase shift between the phase of the quantum bit and the phase of the reference clock can be estimated and corrected by the method in the present embodiment.

FIG. 4B is an enlarged view of a change in the frequency f_{q1} of the selected quantum bit near t1 in FIG. 3. At t1, ideally, f₀ instantaneously changes to f₊ (line 410) as shown in FIG. 3. However, actually, for example, a phenomenon such as switching with a delay of a delay time t (line 411), linear switching (line 412), transient response switching (line 413), or combination thereof occurs, and it is considered that the frequency is switched to f₊ after a finite delay time τ. Therefore, when phase tracking is performed assuming that the frequency is an ideal line 410, an error (phase shift) occurs.

A phase shift amount (a shift amount between a reference phase and an actual quantum bit phase) Δφ is as Formula 3.

$$\begin{matrix}[ Math . 3 ] & \\ Δϕ = 2 π \vert {\int }_{t 1}^{τ} {f}_{tracking} ( {t}^{′} ) - {f}_{real} ( {t}^{′} ) {dt}^{′} \vert & ( Formula 3 )\end{matrix}$$

Here, f_{tracking} and fᵣₑₐₗ respectively represent a (ideal) frequency assumed in phase tracking resonance frequency of an actual quantum bit, and τ represents a time taken for the resonance frequency of the quantum bit to transition from f₀ to f₊. τ is, for example, 1 nsec or less.

Due to an unstable portion in FIG. 4B, a current amount (proportional to frequency) that flows until being stabilized at f₊ is not known. When it is not known a trajectory that is taken to reach f₊ during τ, because a phase shift amount which is an integrated value of the frequency is not known, it is necessary to control the trajectory regardless of a length of τ. Here, an allowable amount of the phase shift Δφ necessary for maintaining accuracy of the quantum computation is estimated.

FIG. 4C shows a relationship (F=cos²(Δφ)) between the gate fidelity (F) indicating performance of a quantum gate and a phase shift in the case of assuming π rotation gate. Thus, F>99.99% can be achieved by setting Δφ<2π×0.0016 (rad).

Next, a typical phase shift amount is estimated. Typically, τ=1 ns and |f₊−f₀|=about 10 MHz. At this time, in FIG. 4B, when f_{tracking} is the line 410 and fᵣₑₐₗ is the line 411, from the formula 2, Δφ=2π|f₊−f₀|τ=2π×0.01.

When f_{tracking} is the line 410 and fᵣₑₐₗ is the line 412, Δφ=π|f₊−f₀|τ=2π×0.005. These cannot satisfy F=99.99%.

The phase shift amount Δφ is proportional to an area surrounded by the ideal line 410 of a frequency assumed in the phase tracking in FIG. 4B and a line of the resonance frequency of an actual quantum bit (lines 411 to 413 or a line formed by a combination thereof).

Therefore, in order to further reduce Δφ, it is necessary to (1) reduce a transition time τ or (2) reduce a difference between f_{tracking} and fᵣₑₐₗ. However, it is generally difficult to make (1) smaller.

Therefore, considering (2), it is important to estimate fᵣₑₐₗ as accurately as possible. For example, by using a circuit simulator or the like, a time waveform of fᵣₑₐₗ taking into account an influence of parasitic capacitance or the like can be predicted with high accuracy, and accordingly, the phase shift amount Δφ can be further reduced.

### [Solution Method by Current and Charge Measurement]

A resonance frequency shift amount of the quantum bit is substantially proportional to a magnetic flux density at a quantum bit position, and according to Ampere's circuital law, the magnetic flux density is proportional to a current amount flowing through the interconnect.

Therefore, regarding Δφ, by the formula 2, a relationship of Formula 4 is obtained.

$$\begin{matrix}[ Math . 4 ] & \\ \begin{matrix}Δϕ ∝ \vert {\int }_{t 1}^{τ} {I}_{tracking} ( {t}^{′} ) {dt}^{′} - {\int }_{t 1}^{τ} {I}_{real} ( {t}^{′} ) {dt}^{′} \vert \\ ∝ \vert {Q}_{tracking} ( τ ) - {Q}_{real} ( τ ) \vert\end{matrix} & ( Formula 4 )\end{matrix}$$

Here, I_{tracking} and Q_{tracking} in the control unit 201 are values that can be freely set to obtain a desired f_{tracking}. That is, if it is possible to know in advance the current Iᵣₑₐₗ actually flowing through the interconnect and the charge amount Qᵣₑₐₗ flowing through the interconnect, it is possible to appropriately set I and Q that form a static magnetic field and bring the phase shift amount Δφ close to 0.

### [Feedback (Calibration)]

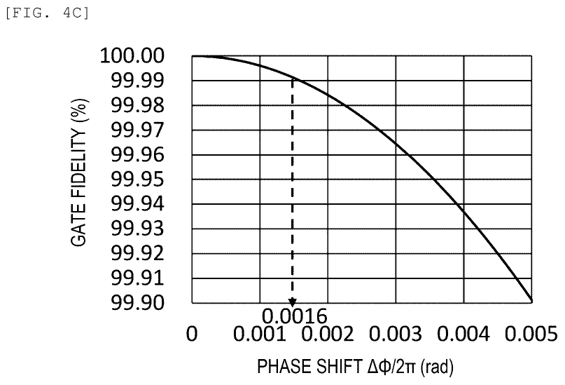

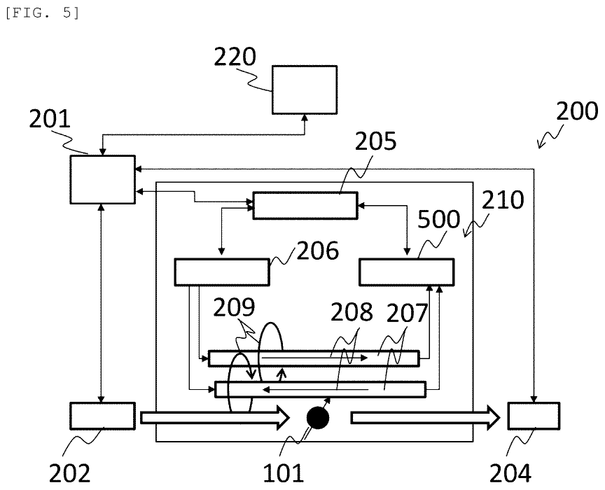

FIG. 5 shows a system configuration for measuring the current Iᵣₑₐₗ flowing through the interconnect and the charge amount Qᵣₑₐₗ flowing through the interconnect with high accuracy. In this figure, a current or charge readout unit 500 is added to the configuration in FIG. 2. The current or charge readout unit 500 is connected to the interconnect 207 and the controller 205, detects a value of a current flowing through the interconnect or a charge amount which is a time integral thereof, and transmits the detected value or the charge amount to the controller 205. This is constituted by, for example, an ammeter or a charge storage (charging) and readout circuit using a capacitor or the like. The current or the charge readout unit 500 can be implemented by, for example, a circuit that stores a current flowing through the interconnect in a capacitor having a known capacitance C.

When a voltage V of the capacitor is measured at the time τ, Qᵣₑₐₗ can be measured based on V=Q/C. For example, the current value Iᵣₑₐₗ of the current flowing through the interconnect can be measured using a current mirror circuit. With this method, Iᵣₑₐₗ or Qᵣₑₐₗ can be detected.

Thus, for example, Iᵣₑₐₗ or Qᵣₑₐₗ of each interconnect is detected in advance, and the information is used during actual quantum computation, so that the phase shift amount Δφ can be brought close to 0. Iᵣₑₐₗ Or Qᵣₑₐₗ is detected in real time, and Iᵣₑₐₗ or Qᵣₑₐₗ can be controlled by threshold value control or feedback control, thereby making it possible to bring the phase shift amount Δφ close to 0.

Since there are a plurality of interconnects, by inserting a switching circuit, it is also possible to detect a current value or a charge amount of the plurality of interconnects by a small number of currents or the charge readout unit 500.

FIG. 6 is a schematic diagram of a configuration in which a switching circuit is inserted. For the quantum bit array 100, switching units 601 and 602 are connected to the interconnects in the X direction and the Y direction, respectively, and a current or the charge readout unit 500 is provided ahead of the switching units 601 and 602.

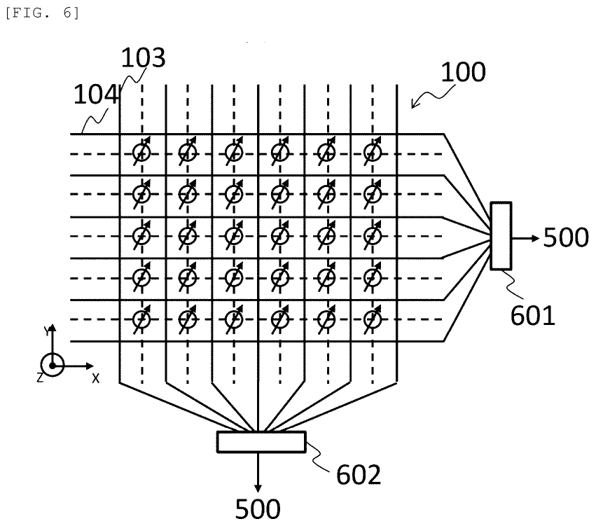

FIG. 7A shows an example of a calibration method. When a command to start calibration (S700) is sent from the host 220 to the control unit 201, the control unit 201 sends a command for switch setting (S701) to the controller 205, and an interconnect to which a current is applied by the current applying unit 206 and a current or an interconnect for reading the current from the charge readout unit 500 are switched and selected by the switching units 601 and 602.

Thereafter, interconnect current application (S702) is performed by the current applying unit 206, charge amount measurement (S703) is performed by the current or the charge readout unit 500, and a measurement result is stored in a memory by the controller 205.

The measurement results stored in the memory are IDs of the interconnects 103 and 104 and the corresponding Qᵣₑₐₗ and Iᵣₑₐₗ.

FIG. 7B is an example of calibration data that is a measurement result of Iᵣₑₐₗ stored in the memory. Data immediately after t1 (reference time is 0 sec) in FIG. 3 is shown. As shown in FIG. 4B, since a period immediately after a current switching timing is particularly problematic as shown in FIG. 4B, data may be recorded from t1 to a predetermined time after t5 in FIG. 3, or the data around t1, t4, and t5 may be cut out and recorded. By using such data for calibration, the phase shift amount Δφ can be brought close to 0.

By performing the above sequence until an end of all interconnects (S705), Iᵣₑₐₗ or Qᵣₑₐₗ of all the interconnects can be detected. Accordingly, since it is possible to detect an accurate Iᵣₑₐₗ or Qᵣₑₐₗ taking into account an influence of parasitic capacitance or the like specific to each interconnect, the phase shift amount Δφ can be effectively brought close to 0.

In one method, Iᵣₑₐₗ or Qᵣₑₐₗ is detected in real time, and I or Q to be passed is controlled by threshold value control or feedback control. In the feedback control, a general feedback circuit can be used to detect Iᵣₑₐₗ or Qᵣₑₐₗ, and the supplied I or Q can be controlled such that, for example, a difference with I_{tracking} or Q_{tracking} becomes zero, and accordingly, the phase shift amount Δφ can be brought close to 0.

Alternatively, in the threshold value control, by changing an operation depending on whether Iᵣₑₐₗ or Qᵣₑₐₗ is smaller or larger than a threshold value, Iᵣₑₐₗ or Qᵣₑₐₗ is made closer to the I_{tracking} or Q_{tracking}. For example, an integrated value is controlled by making constant a value a of current that flows when Iᵣₑₐₗ or Qᵣₑₐₗ reaches a predetermined value using the threshold value.

### [Feedforward]

For example, I and Q supplied to obtain a desired Iᵣₑₐₗ or Qᵣₑₐₗ are determined in advance based on calibration data as shown in FIG. 7B, and the current is controlled based on the data.

FIG. 7C shows an example of correction data set based on the calibration data. By using a constant current source or a charge pump circuit to pass a predetermined current amount or charge amount through the interconnect, Iᵣₑₐₗ or Qᵣₑₐₗ can be controlled with high accuracy.

For example, in a case of the charge pump circuit, it is assumed that a certain amount of charges Q stored in a capacitor is passed through an interconnect while being counted. A current I(t) flowing through the interconnect has a relationship of I(t)=Q×f(t), where f(t) is a frequency (counted frequency) at which the charge Q is sent to the interconnect. When Q is constant, since I(t) is proportional to f(t), if f(t) can be controlled so as to be gradually increased from 0 until a desired current amount is reached, Iᵣₑₐₗ such as the line 412 shown in FIG. 4B can be achieved with high precision control. Accordingly, by matching I_{tracking} in the formula 4 and Iᵣₑₐₗ, the phase shift amount Δφ can be brought close to 0.

### [Summary of Effects of Embodiment 1]

As described above, the shift amount between the reference phase and the actual quantum bit phrase can be reduced, and the single-qubit gate operation can be performed with low errors.

### Embodiment 2

In the present embodiment, a basic configuration is similar as that of Embodiment 1, but a microwave pulse irradiation method is different in order to reduce an influence of crosstalk on the non-selected quantum bit. At this time, since it is expected that an influence of an error due to a phase shift between a reference phase and an actual quantum bit phrase becomes more remarkable, a phase shift reduction method described in Embodiment 1 is more effective. Accordingly, a shift amount between the reference phase and the actual quantum bit phrase can be reduced while reducing the influence of the crosstalk on the non-selected quantum bit, and a single-qubit gate operation can be performed with low errors.

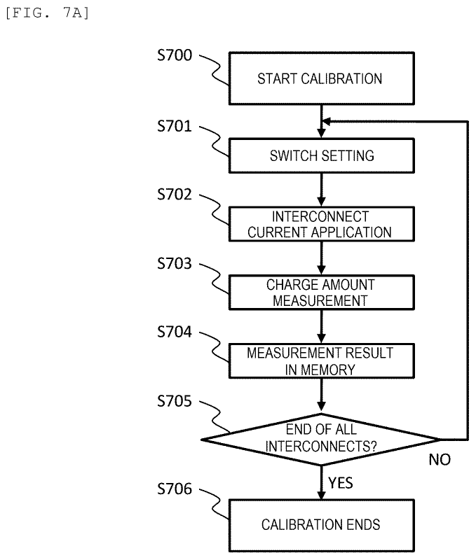

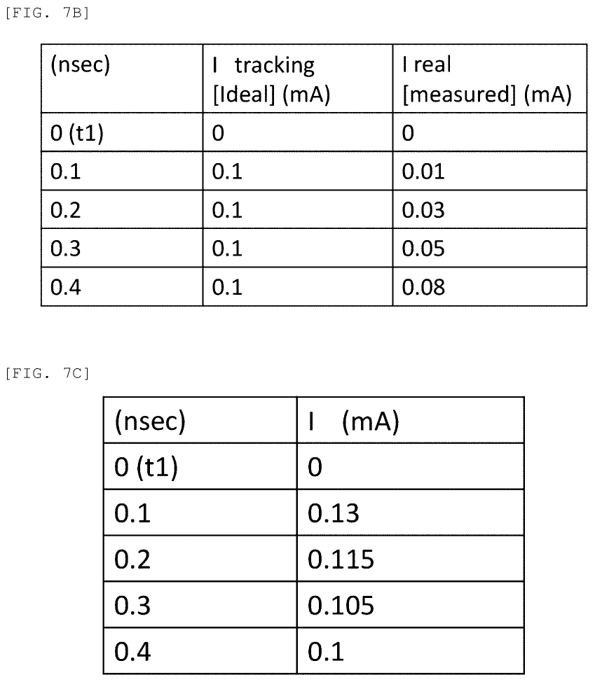

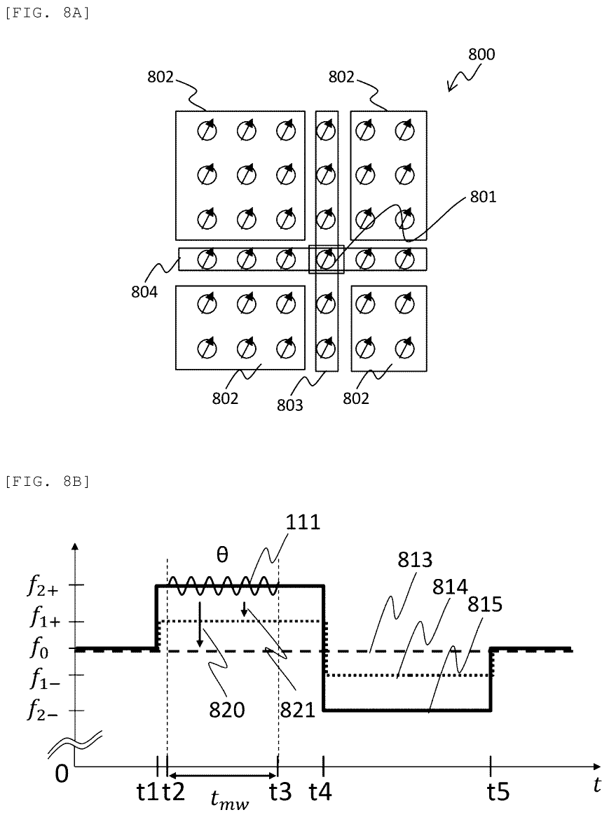

A frequency shift depicted in FIG. 8A and the subsequent drawings is caused by a magnetic field, and a magnitude of the shift is proportional to the magnetic field. The magnetic field is controlled by a current flowing through each line. First, an outline of Embodiment 2 and subsequent embodiments will be briefly described in correspondence with the drawings.

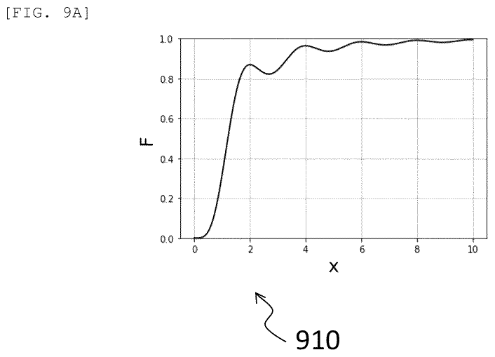

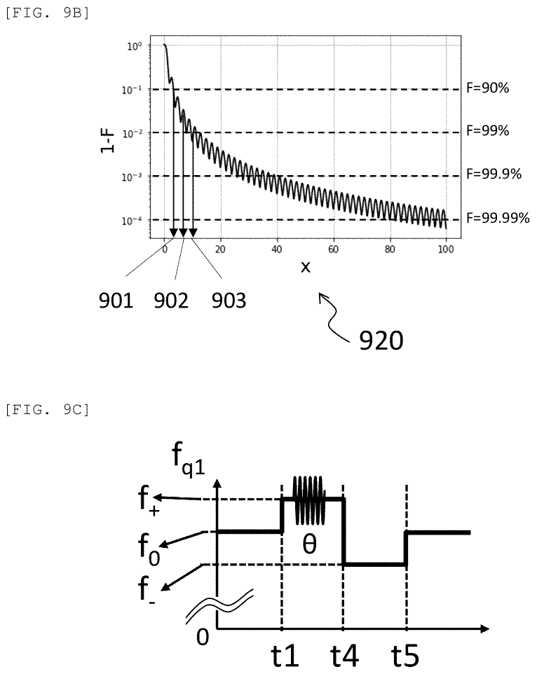

Specifically, a first magnetic field (a magnetic field at t1 to t4 in FIGS. 8B and 9E) is applied to a target charge (801 in FIG. 8A) by a current flowing through a first line (word line) and the second line (bit line), and then a second magnetic field (a magnetic field at t4 to t5 in FIGS. 8B and 9E) having a magnitude same as a magnitude of the first magnetic field and a direction opposite to a direction of the first magnetic field is applied, and a microwave is used to irradiate a charge for at least a part of a period during which the first magnetic field is applied and at least a part of the period during which the second magnetic field is applied (see FIGS. 9E and 8A to 10G).

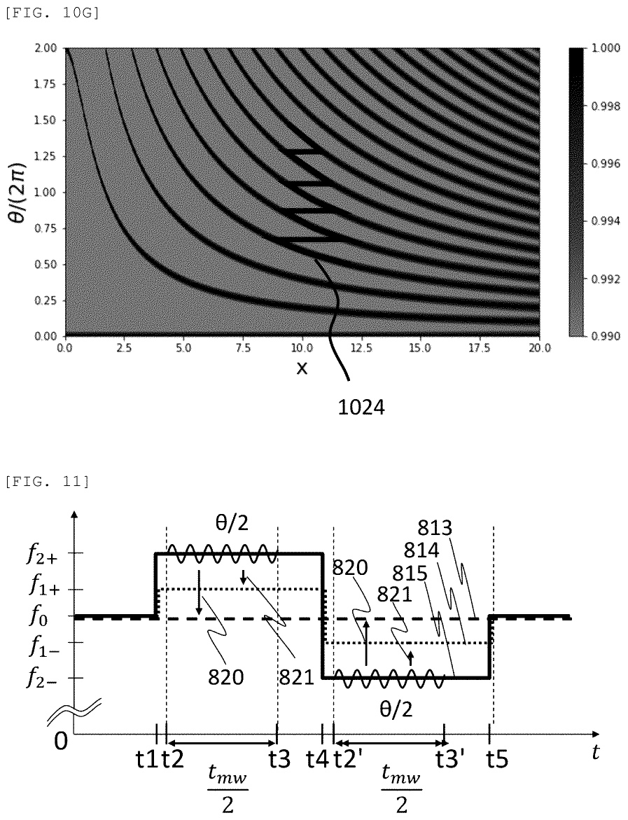

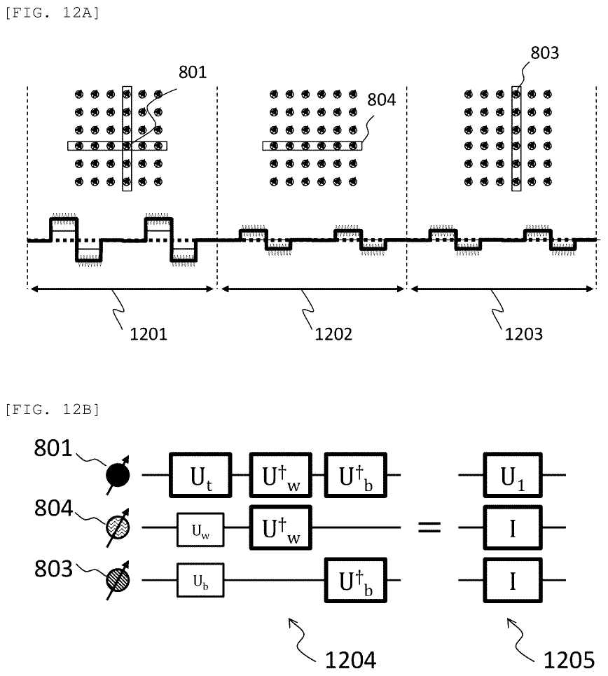

More preferably, by passing the current through the first line, a third magnetic field is formed, and then, a fourth magnetic field having a magnitude same as a magnitude of the third magnetic field and a direction opposite to a direction of the third magnetic field is formed (1202 in FIG. 12A), by passing the current through the second line, a fifth magnetic field is formed, and then, a sixth magnetic field having a magnitude same as a magnitude of the fifth magnetic field and a direction opposite to a direction of the fifth magnetic field is formed (1203 in FIG. 12A), the magnitudes of the third magnetic field, the fourth magnetic field, the fifth magnetic field, and the sixth magnetic field are smaller than the magnitudes of the first magnetic field and the second magnetic field, and the microwave is used to irradiate the charge for at least a part of a period during which the third magnetic field is applied, a part of a period for which the fourth magnetic field is applied, a part of a period during which the fifth magnetic field is applied, and a part of a period during which the sixth magnetic field is applied (see FIGS. 11 to 12B).

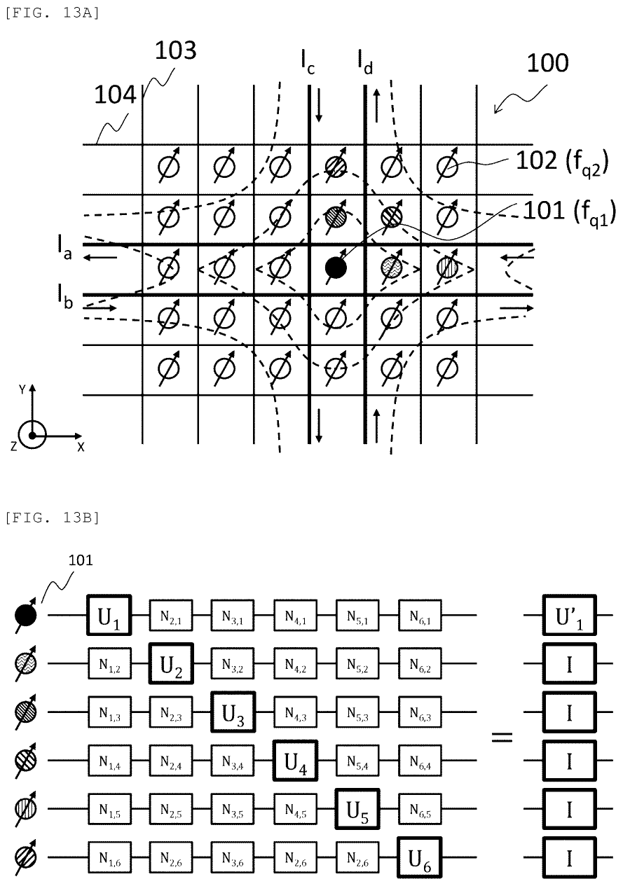

More preferably, by passing a current through another line parallel to the first line, a seventh magnetic field is formed, and then, an eighth magnetic field having a magnitude same as a magnitude of the seventh magnetic field and a direction opposite to a direction of the seventh magnetic field is formed, by passing a current through another line parallel to the second line, a ninth magnetic field is formed, and then, a tenth magnetic field having a magnitude same as a magnitude of the ninth magnetic field and a direction opposite to a direction of the ninth magnetic field is formed (in a specific example, a current is passed through a bit line and a word line apart from a target bit in FIG. 13A), the magnitudes of the seventh magnetic field, the eighth magnetic field, the ninth magnetic field, and the tenth magnetic field are smaller than the magnitudes of the first magnetic field and the second magnetic field, and the microwave is used to irradiate the charge for at least a part of a period during which the seventh magnetic field is applied, at least a part of a period during which the eighth magnetic field is applied, at least a part of a period during which the ninth magnetic field is applied, and at least a part of a period during which the tenth magnetic field is applied (see FIGS. 13A and 13B).

### [Problem of Crosstalk on Non-Selected Quantum Bit]

FIG. 8A shows a classification diagram of quantum bits in a quantum bit array 800. The selected quantum bit 801 to be subjected to a single-qubit gate operation, a quantum bit string 803 whose resonance frequency is shifted by a local magnetic field for Y-direction (bit line) selection, a quantum bit string 804 whose resonance frequency is shifted by a local magnetic field for X-direction (word line) selection, and other non-selected quantum bits 802 are shown.

FIG. 8B shows changes over time in the resonance frequencies 813, 814, and 815 of three types of quantum bits. The resonance frequency 815 of the selected quantum bit 801 shifts from the frequency f₀ to a frequency f₂₊ in the vicinity of the time t1, is applied with the microwave pulse 111 matching a frequency f₂₊ between the times t2 and t3, shifts to a frequency f₂₋ in the vicinity of the time t4, and then returns to the frequency f₀ in the vicinity of the time t5.

On the other hand, the resonance frequency 813 of the non-selected quantum bit 802 has no frequency fluctuation and is fixed at f₀. Further, the resonance frequency 814 of the quantum bit string 803 on the bit line and the quantum bit string 804 on the word line is shifted, for example, from the frequency f₀ to a frequency f₁₊ which is half of the frequency f₂₊, is shifted to a frequency f₂₋ which is half of the frequency f₂₋, and returns to the frequency f₀.

Here, an influence of the microwave pulse 111 matching the frequency f₂₊ affects not only the selected quantum bit 801 but also, to a certain extent, the non-selected quantum bit 802 and the quantum bit strings 803 and 804 on the bit line and word line. This influence is called crosstalk.

The crosstalk is an influence of a frequency of the microwave pulse and a detuned resonance frequency on a quantum bit, and generally the greater a frequency difference, the smaller the influence. However, in order to increase detuning, it is necessary to increase a local magnetic field, and thus it is necessary to increase a current amount to the interconnect, which poses a problem of non-negligible heat generation in a refrigerator. Therefore, a method of reducing the influence of the crosstalk is described below.

Particularly, in the present embodiment, a method of reducing crosstalk 820 on the non-selected quantum bit 802 will be described. A method of reducing crosstalk 821 to the quantum bit strings 803 and 804 on the bit line and the word line in Embodiment 3 will be described.

### [Method of Reducing Crosstalk to Non-Selected Quantum Bit]

In FIG. 9A, the influence of crosstalk on the quantum bit is indicated by a parameter F. A horizontal axis x is a numerical value obtained by normalizing a difference between a resonance frequency of the quantum bit and a frequency of the microwave pulse by Rabi oscillations. A quantum gate is assumed to be a π gate. When the influence of crosstalk is considered, F=1 when there is no influence of the microwave pulse on the quantum bit at all. This is achieved when a frequency difference is sufficiently large from x to ∞. It can be seen that the smaller x is, the closer the frequencies are, and the lower F is due to an influence of the microwave pulse.

FIG. 9B shows a graph of FIG. 9A in which a vertical axis is 1−F and the graph is displayed on a LOG scale. When a quantum gate operation is performed on the selected quantum bit, for example, the non-selected quantum bit 802 is x=10 (903) and F=about 99%, the quantum bit strings 803 and 804 on the bit line and the word line are x=8 (902) and F=about 95%, and a quantum bit closest to the selected quantum bit 801 is x=5 (901) and F=about 90%. On the other hand, since F=99.99% or more is practically desired, a decrease in F due to the influence of crosstalk is a serious problem.

FIG. 9C shows a change over time in the resonance frequency of the selected quantum bit 801 (referred to as a single irradiation method) in one method of performing θ rotation gate using the Rabi oscillation. Here, θ is a rotation angle of a spin and takes a value of 0 to 2π. This is a case where t4−t1=t5−t4 as in FIG. 8B. In this case, a phase difference between the non-selected quantum bit or the quantum bits on the bit line and word line and the selected quantum bit can be cancelled as shown in FIG. 4A, but the influence of the crosstalk occurs.

FIG. 9D shows a change over time in a resonance frequency of the selected quantum bit 801 when a quantum gate operation time is reduced to about half by setting t4−t1>t5−t4 in the single irradiation method. In this case as well, it is possible to cancel a phase shift between the non-selected quantum bit and the selected quantum bit by using 2π periodicity of the phase. However, due to an imbalance between a (+) frequency shift and a (−) frequency shift, it is not possible to cancel all phase shifts simultaneously for quantum bits on the bit line and word line or for neighboring quantum bits.

FIG. 9E shows a change over time in a resonance frequency of the selected quantum bit 801 according to a method proposed in the embodiment. As shown in the drawing, the method of the embodiment is a method of performing irradiation with a microwave pulse twice, each at θ/2 (referred to as a twice irradiation method). In this method, a quantum gate operation time can be reduced to about a half of that of the single irradiation method in FIG. 9C. In addition, since the (+) frequency shift and the (−) frequency shift are well balanced, all phase shifts can be cancelled simultaneously for the non-selected quantum bit, the quantum bits on the bit line and word line, and the neighboring quantum bit as in FIG. 9C. Further, the present method is characterized in that the influence of crosstalk can be cancelled as described below.

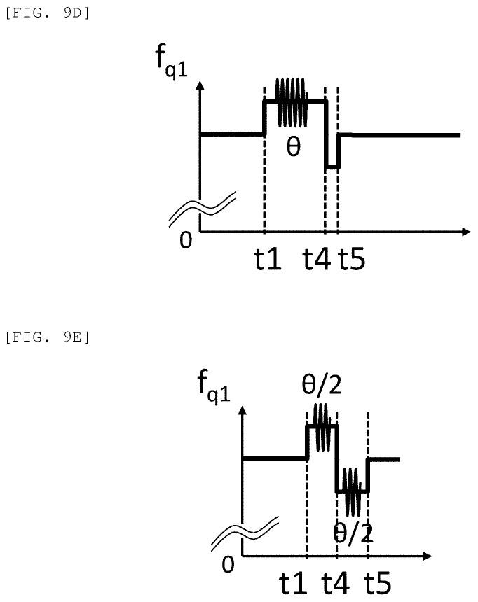

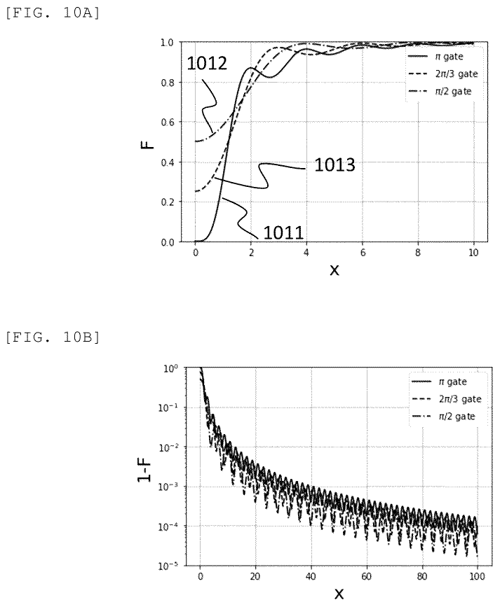

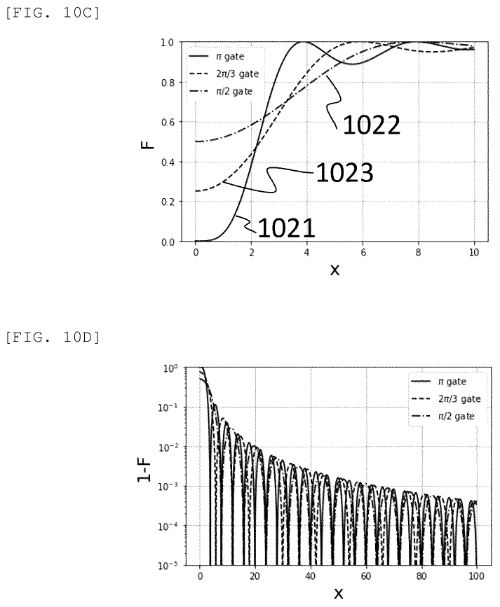

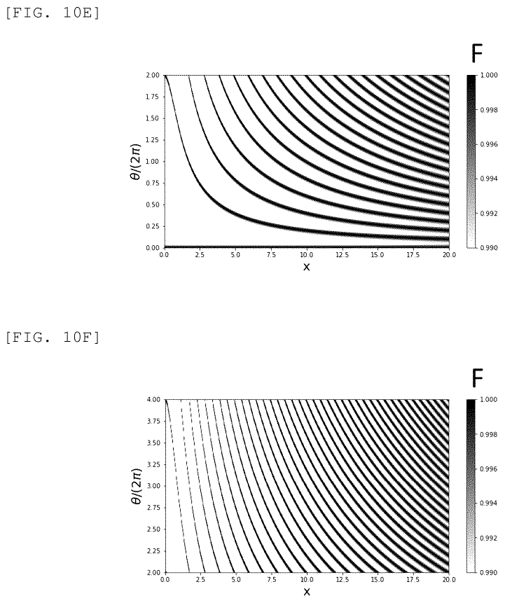

The influence of crosstalk on F is shown in linear and log plots for the single irradiation method shown in FIGS. 10A and 10B, and the twice irradiation method shown in FIGS. 10C and 10D.

As shown in FIG. 10A, it is difficult for a π gate line 1011, a 2π/3 gate line 1013, and a π/2 gate line 1012 to satisfy F=1 in the single irradiation method.

As shown in FIG. 10B, which shows FIG. 10A in logarithm, it is necessary to set x to about 100 in order to set F=1−10\hat{ }(−4), for example. In order to bring F close to 1, it is necessary to set x to a large value, and it is necessary to apply a large current in order to apply a large local magnetic field. Accordingly, from a viewpoint of heat generation, it is difficult in design to increase x to 10 or more.

On the other hand, as shown in FIG. 10C, in a case of the twice irradiation method, in a π gate line 1021, a 2π/3 gate line 1023, and a π/2 gate line 1022, there exists x where F=1 periodically.

As shown in FIG. 10D, which shows FIG. 10C in logarithm, F=1 can be achieved by appropriately setting x according to a rotation angle of a spin in a quantum gate operation. Thus, in principle, it is possible to achieve the quantum gate operation that reduces the influence of crosstalk by the twice irradiation method.

FIG. 10E shows a relationship between the angle θ of a quantum gate operation and x. A black line represents a region where F is approximately 99.5% or more. From the drawing, it is understood that a desired θ (+2nπ, n is an integer) can be achieved by appropriately selecting x.

As shown in FIG. 10F, as θ becomes larger, a period in a direction of x in which F=1 becomes finer, so that a desired θ can be achieved in a small range of x.

FIG. 10G shows an example of a method for achieving a desired θ. For example, when an operation is performed in a range of θ=π to 3π, for example, by using a combination of (θ, x) satisfying a condition on a line 1024, x corresponding to any θ (excluding periodicity from 0 to 2π) is set, and F=1 can be achieved in principle.

A waveform of the microwave pulse in the present embodiment is assumed to be, for example, a rectangular wave. The influence of crosstalk can be reduced by, for example, a Gaussian waveform, or a Sech waveform. In this case, if the waveform is long to some extent, the influence of crosstalk can be reduced almost without depending on the frequency. In this case as well, the method of reducing the crosstalk according to the twice irradiation method is effective.

### Embodiment 3

In the present embodiment, a basic configuration is similar as that of Embodiment 2, but a quantum gate operation method is different in order to reduce crosstalk on a bit line and word line. At this time, since it is expected that an influence of an error due to a phase shift between a reference phase and an actual quantum bit phase becomes more remarkable, the phase shift reduction method described in Embodiment 1 is more effective. Accordingly, a shift amount between the reference phase and the actual quantum bit phrase can be reduced while reducing the influence of the crosstalk on the bit line and word line, and a single-qubit gate operation can be performed with low errors.

FIG. 11 is a conceptual diagram of a twice irradiation method. It is described in Embodiment 2 that the crosstalk 820 to the non-selected quantum bit 802 can be removed by the twice irradiation method. On the other hand, the crosstalk (referred to as B/W crosstalk) 821 on the quantum bit strings 803 and 804 on the bit line and word line cannot be removed. Therefore, a method of removing the B/W crosstalk will be described.

### [Method of Reducing Crosstalk on Bit Line and Word Line]

In order to remove crosstalk on the non-selected quantum bit 802, the twice irradiation method is adopted. Further, in order to achieve a unitary matrix of any single-qubit gate, it is necessary to perform spin rotation by twice Rabi oscillations while changing the phase. Therefore, when the twice irradiation method is used for single spin rotation, a total of four times microwave pulse irradiations are required. Using a quantum gate operation by these four times pulse irradiations as a basic unit, B/W crosstalk can be removed by performing gate operations three times in succession (called a three-gate method).

FIG. 12A is a conceptual diagram of the three-gate method. A first, second, and third quantum gate operations are 1201, 1202, and 1203, respectively. Each quantum gate operation can achieve a quantum operation corresponding to any unitary matrix U.

In the quantum gate operation 1201, Uₜ acts on the selected quantum bit 801, U_{w} acts as crosstalk on the quantum bit string 804 on the word line, and U_{b} acts as crosstalk on the quantum bit string 803 on the bit line. At this time, crosstalk on the non-selected quantum bit 802 is removed by the twice irradiation method.

Subsequently, in the quantum gate operation 1202, a quantum gate operation is performed only on the quantum bit string 804 on the word line, and U_{w}^{†} acts on quantum bits on the word line including the selected quantum bit 801.

Finally, in the quantum gate operation 1203, a quantum gate operation is performed only on the quantum bit string 803 on the bit line, and U_{b}^{†} acts on quantum bits on the bit line including the selected quantum bit 801.

FIG. 12B shows the above operation as a quantum circuit diagram 1204. Here, the series of quantum circuit diagrams 1204 are finally represented by a quantum circuit diagram 1205, and it is necessary that the desired quantum gate operation U₁ is performed only on the selected quantum bit and the B/W crosstalk is removed (that is, an identity (I) gate is performed).

Therefore, it is necessary to determine Uₜ, U_{w}^{†}, and U_{b}^{†} so as to satisfy Formula 5.

$$\begin{matrix}[ Math . 5 ] & \\ {U}_{t} {U}_{w}^{†} {U}_{b}^{†} = {U}_{1} & ( Formula 5 )\end{matrix}$$

Since the influence of crosstalk can be obtained by an ordinary computer, a parameter of each quantum gate operation can be determined so as to satisfy Formula 5. By this three-gate method, it is possible to remove crosstalk on other quantum bits and perform a quantum gate operation only on the selected quantum bit.

### Embodiment 4

In Embodiment 3, the three-gate method that removes the influence of crosstalk on the three types of quantum bits (the non-selected quantum bit 802, the quantum bit string 804 on the word line, and the quantum bit string 803 on the bit line) shown in FIG. 8A is described.

However, the method in Embodiment 3 is based on an ideal situation that all of the three types of quantum bits have the same (that is, frequency three types of frequencies). Actually, there are quantum bits having frequencies other than the three frequencies due to an influence of a leakage magnetic field described below.

In the present embodiment, a basic configuration is similar as that of Embodiment 3, but a quantum gate operation method is different in order to reduce crosstalk due to the leakage magnetic field. At this time, since it is expected that an influence of an error due to a phase shift between a reference phase and an actual quantum bit phase becomes more remarkable, the phase shift reduction method described in Embodiment 1 is more effective. Accordingly, a shift amount between the reference phase and the actual quantum bit phrase can be reduced while reducing the influence of the crosstalk due to the leakage magnetic field, and a single-qubit gate operation can be performed with low errors.

FIG. 13A shows contour lines of a static magnetic field distribution generated when currents flow through Iₐ, I_{b}, I_{c}, and I_{d} in directions of arrows. Although a current is passed for the purpose of applying a local static magnetic field to the selected quantum bit 101, the local static magnetic field affects neighboring quantum bits. The influence of the “leakage magnetic field” cannot be removed only by a crosstalk removal method in Embodiment 3.

FIG. 13B shows a schematic diagram of an “N-gate method” in which crosstalk due to the leakage magnetic field is removed. The N-gate method is an extension of the three-gate method in Embodiment 3. For example, it is assumed that there are six types of frequency for frequency shift quantum bits due to the leakage magnetic field whose degree of influence cannot be ignored.

The six types include a frequency of the selected quantum bit, a frequency of the quantum bit near the selected quantum bit, and the frequencies of the quantum bit on the bit line and the word line. At this time, N=6, that is, a six-gate method.

Thus, N is the number of types of quantum bit frequencies+1 at which the influence of crosstalk cannot be ignored (becomes a certain threshold value or more). As shown in FIG. 13B, by combining the gate operations N times, it is possible to perform the quantum gate operation only on the selected quantum bit. The quantum gates of U₁ to U₆ are all performed by the twice irradiation method, and in consideration of crosstalk (N_{*}, _{*}) due to these gates, a parameter of each quantum gate can be calculated by an ordinary computer so as to achieve a desired quantum gate U₁′ as in the three-gate method. The quantum gates related to the quantum bits other than the selected quantum bit are not necessarily I, and any quantum gate operation may be set.

According to the above embodiment, the single-qubit gate operation can be performed with a low error in a quantum bit array with a dynamic resonance frequency changing method in which quantum bits are integrated. Since a practical quantum computer can be implemented, energy consumption can be reduced and carbon emission can be reduced, contributing to slowing of global warming and development of a sustainable society.

### REFERENCE SIGNS LIST

quantum bit 101
interconnect 103
interconnect 104
interconnect 105
interconnect 106

1. A quantum bit array comprising:
a semiconductor layer;
an insulating layer disposed on the semiconductor layer;
a plurality of first electrodes provided on the insulating layer and configured to trap a charge in a predetermined spin state in the semiconductor layer by applying a voltage;
a plurality of second electrodes provided on the insulating layer and configured to form a magnetic field acting on the charge by passing a current;
a current applying unit configured to pass a current to at least one of the second electrodes to form a magnetic field acting on the charge when the spin state of the charges is changed;
a microwave generating source configured to irradiate the charge with a microwave; and
a current measuring unit configured to measure current flowing through the second electrode.

2. The quantum bit array according to claim 1, wherein
the current measuring unit measures a charge amount flowing to the second electrode in a predetermined period.

3. The quantum bit array according to claim 1, wherein
a plurality of charges are trapped in the semiconductor layer, and
the second electrode applies a first magnetic field to a target charge, which is a part of charges of a plurality of charges whose spin states are to be changed, and does not apply the first magnetic field to other charges.

4. The quantum bit array according to claim 3, wherein
a current flowing through the second electrode for applying the first magnetic field is controlled based on data of the current flowing through the second electrode measured by the current measuring unit.

5. The quantum bit array according to claim 4, wherein
control over the current is feedback control or feedforward control.

6. The quantum bit array according to claim 4, further comprising:
a control unit having a function of generating a reference clock that matches a frequency of a precession of a spin of the charge, and tracking a phase of the precession using the reference clock, with both the phase of the precession of the spin of the charge and a phase of the microwave at an irradiation timing of the microwave as an initial phase.

7. The quantum bit array according to claim 4, wherein
the second electrode applies the first magnetic field to the target charge, and then applies a second magnetic field having a magnitude same as a magnitude of the first magnetic field and a direction opposite to a direction of the first magnetic field, and
the microwave generating source irradiates the charge with a microwave for at least a part of a period during which the first magnetic field is applied and at least a part of a period during which the second magnetic field is applied.

8. The quantum bit array according to claim 7, wherein
the second electrode is implemented by a plurality of first lines extending in a first direction and a plurality of second lines extending: in a second direction and constitutes a matrix,
the target charge is specified by a predetermined first line and a predetermined second line, and
the current applying unit passes a current through the predetermined first line and the predetermined second line to apply the first magnetic field to the target charge, and then applies the second magnetic field.

9. The quantum bit array according to claim 8, wherein
the current applying unit passes a current through the predetermined first line to form a third magnetic field, and then forms a fourth magnetic field, and
the current applying unit passes a current through the predetermined second line to form a fifth magnetic field, and then forms a sixth magnetic field.

10. The quantum bit array according to claim 9, wherein
the current applying unit passes a current through a first line other than the predetermined first line to form a seventh magnetic field, and then forms an eighth magnetic field, and
the current applying unit passes a current through a second line other than the predetermined second line to form a ninth magnetic field, and then forms a tenth magnetic field.

11. A method of controlling a quantum bit that controls a spin state of a quantum bit formed by a charge trapped in a semiconductor device, the method of controlling a quantum bit comprising:
when controlling a spin state of a quantum bit formed by a target charge specified by a first line and a second line formed in the semiconductor device,
executing a first step of measuring at least one of a current and a charge amount flowing through the first line and the second line; and
executing a second step of controlling at least one of the current and the charge amount flowing through the first line and the second line based on a measurement result of the first step.

12. The method of controlling a quantum bit according to claim 11, wherein
a reference clock is prepared in order to track a phase of the quantum bit that performs a precession, and a phase of a microwave is set based on a phase of the reference clock assuming that the phase of the reference clock and a phase of the precession match each other, and
in the second step, irradiation is performed with the microwave at a timing when a magnetic field is applied to the target charge by a current flowing through the first line and the second line.

13. The method of controlling a quantum bit according to claim 12, wherein
by the current flowing through the first line and the second line, a first magnetic field is applied to the target charge, and then a second magnetic field having a magnitude same as a magnitude of the first magnetic field and a direction opposite to a direction of the first magnetic field is applied, and
the microwave is used to irradiate the charge for at least a part of a period during which the first magnetic field is applied and at least a part of a period during which the second magnetic field is applied.

14. The method of controlling a quantum bit according to claim 13, wherein
by passing the current through the first line, a third magnetic field is formed, and then, a fourth magnetic field having a magnitude same as a magnitude of the third magnetic field and a direction opposite to a direction of the third magnetic field is formed,
by passing the current through the second line, a fifth magnetic field is formed, and then, a sixth magnetic field having a magnitude same as a magnitude of the fifth magnetic field and a direction opposite to a direction of the fifth magnetic field is formed,
the magnitudes of the third magnetic field, the fourth magnetic field, the fifth magnetic field, and the sixth magnetic field are smaller than the magnitudes of the first magnetic field and the second magnetic field, and
the microwave is used to irradiate the charge for at least a part of a period during which the third magnetic field is applied, a part of a period during which the fourth magnetic field is applied, a part of a period during which the fifth magnetic field is applied, and a part of a period during which the sixth magnetic field is applied.

15. The method of controlling a quantum bit according to claim 14, wherein
by passing a current through another line parallel to the first line, a seventh magnetic field is formed, and then, an eighth magnetic field having a magnitude same as a magnitude of the seventh magnetic field and a direction opposite to a direction of the seventh magnetic field is formed,
by passing a current through another line parallel to the second line, a ninth magnetic field is formed, and then, a tenth magnetic field having a magnitude e same as a magnitude of the ninth magnetic field and a direction opposite to a direction of the ninth magnetic field is formed,
the magnitudes of the seventh magnetic field, the eighth magnetic field, the ninth magnetic field, and the tenth magnetic field are smaller than the magnitudes of the first magnetic field and the second magnetic field, and
the microwave is used to irradiate the charge for at least a part of a period during which the seventh magnetic field is applied, at least a part of a period during which the eighth magnetic field is applied, at least a part of a period during which the ninth magnetic field is applied, and at least a part of a period during which the tenth magnetic field is applied.
